(19) United States
(12) Patent Application Publication
(10) Pub. No.: US 2023/0108468 A1
(43) Pub. Date: Apr. 6, 2023

(54) DISPLAY SCREEN ASSEMBLY, ELECTRONIC DEVICE, AND IMAGE ACQUISITION METHOD

(71) Applicant: GUANGDONG OPPO MOBILE TELECOMMUNICATIONS CORP., LTD., Dongguan Guangdong (CN)

(72) Inventor: Zhilin LI, Dongguan Guangdong (CN)

(21) Appl. No.: 18/059,941

(22) Filed: Nov. 29, 2022

Related U.S. Application Data
(63) Continuation of application No. PCT/CN2021/091472, filed on Apr. 30, 2021.

(30) Foreign Application Priority Data
Jun. 28, 2020 (CN) 202010599855.6

(51) Int. Cl. H04N 23/63; G02F 1/015; H10K 59/50; H10K 59/65; H10K 50/818; H04N 23/53; H04N 23/80; H04N 23/56; G09G 3/32

(52) U.S. Cl. CPC H04N 23/63; G02F 1/015; G09G 3/32; H01L 27/3232; H01L 27/3234; H01L 51/5218; H04N 23/53; H04N 23/56; H04N 23/80; G09G 2300/0456; H04M 1/0266

(57) ABSTRACT

A display screen assembly, an electronic device, and an image acquisition method are provided. The display screen assembly includes: a display screen including a first region and a second region; a coupling grating, used to couple and transmit an external light being incident toward the first region to the second region; and an electroluminescent device, used to allow the external light to be incident toward the first region or block the external light from being incident toward the first region.

### CROSS REFERENCE OF RELATED APPLICATIONS

This application is a continuation of International Application No. PCT/CN2021/091472, filed Apr. 30, 2021, which claims priority to Chinese Patent Application No. 202010599855.6, filed Jun. 28, 2020, the entire disclosures of which are incorporated herein by reference.

### TECHNICAL FIELD

The disclosure relates to the field of electronic technologies, and more particularly to a display screen assembly, an electronic device, and an image acquisition method.

### BACKGROUND

With the development of the electronic technologies, a size of a display screen in an electronic device such as a smart phone is getting larger and larger, and a screen-to-body ratio of the display screen is also getting higher and higher. In general, the display screen of the electronic device is disposed with a non-display area, which is used to set functional components such as a camera.

In order to further improve the screen-to-body ratio of the display screen, setting the camera below the display screen has gradually emerged in the related art. The camera receives external light passing through the display screen, so as to achieve image acquisition.

### SUMMARY

Embodiments of the disclosure provides a display screen assembly, an electronic device, and an image acquisition method.

In a first aspect, an embodiment of the disclosure provides a display screen assembly, including:

a display screen, including a first region and a second region, and light transmittance of the first region being less than light transmittance of the second region;

a coupling grating, stacked on a side of the display screen, wherein the coupling grating is configured to couple and transmit an external light being incident toward the first region to the second region and pass through the second region; and

an electroluminescent device, stacked on a side of the coupling grating facing away from the display screen, wherein the electroluminescent device faces to the first region, and the electroluminescent device is configured to allow the external light to be incident toward the first region or block the external light from being incident toward the first region.

In a second aspect, an embodiment of the disclosure provides an electronic device, including: [0011] a display screen assembly, including:
a display screen, including a first region and a second region, and light transmittance of the first region being less than light transmittance of the second region;
a coupling grating, stacked on a side of the display screen, wherein the coupling grating is configured to couple and transmit an external light being incident toward the first region to the second region and pass through the second region; and
an electroluminescent device, stacked on a side of the coupling grating facing away from the display screen, wherein the electroluminescent device faces to the first region, and the electroluminescent device is configured to allow the external light to be incident toward the first region or block the external light from being incident toward the first region; and
an optical imaging device, disposed on another side of the display screen, wherein the optical imaging device faces to the second region, and the optical imaging device is configured to receive external light passed through the second region to thereby obtain an image.

In a third aspect, an embodiment of the disclosure provides an image acquisition method, which is applied to an electronic device including a display screen assembly and an optical imaging device, the display screen assembly includes a display screen, a coupling grating, and an electroluminescent device sequentially stacked, and the image acquisition method includes:
in response to the electroluminescent device being turned off, allowing, by the electroluminescent device facing to a first region of the display screen, an external light to pass through the electroluminescent device and be incident toward the first region; coupling and transmitting, by the coupling grating, the external light being incident toward the first region to a second region of the display screen and pass through the second region, and light transmittance of the first region being less than light transmittance of the second region; receiving, by the optical imaging device facing to the second region, the external light being incident toward the first region and passed through the second region, and acquiring a first image through the optical imaging device;
in response to the electroluminescent device being turned on, blocking, by the electroluminescent device, the external light from being incident toward the first region of the display screen; receiving, by the optical imaging device, an external light being incident toward the second region, and acquiring a second image through the optical imaging device; and
generating a final image according to the first image and the second image.

### BRIEF DESCRIPTION OF DRAWINGS

In order to illustrates technical solutions in embodiments of the disclosure more clearly, the following will briefly introduce drawings needed in the description of the embodiments. Apparently, the drawings in the following description are merely some embodiments of the disclosure. For those skilled in the art, other drawings can be obtained from these drawings without any creative effort.

FIG. 1 illustrates a schematic structural view of a first structure of an electronic device according to an embodiment of the disclosure.

FIG. 2 illustrates a schematic structural view of a display screen assembly of the electronic device illustrated in FIG. 1.

FIG. 3 illustrates a schematic structural view of a first structure of a display screen of the display screen assembly illustrated in FIG. 2.

FIG. 4 illustrates a schematic structural view of a second structure of the display screen of the display screen assembly illustrated in FIG. 2.

FIG. 5 illustrates a schematic structural view of a third structure of the display screen of the display screen assembly illustrated in FIG. 2.

FIG. 6 illustrates a schematic view of propagation of light when passing through a coupling grating.

FIG. 7 illustrates a schematic view of a first kind of light propagation in the coupling grating of the display screen assembly illustrated in FIG. 2.

FIG. 8 illustrates a schematic view of a second kind of light propagation in the coupling grating of the display screen assembly illustrated in FIG. 2.

FIG. 9 illustrates a schematic structural view of a second structure of an electronic device according to an embodiment of the disclosure.

FIG. 10 illustrates a schematic structural view of a third structure of an electronic device according to an embodiment of the disclosure.

FIG. 11 illustrates a first schematic view of the electronic device acquiring an image according to the embodiment of the disclosure.

FIG. 12 illustrates a second schematic view of the electronic device acquiring the image according to the embodiment of the disclosure.

FIG. 13 illustrates a schematic structural view of a fourth structure of an electronic device according to an embodiment of the disclosure.

### DETAILED DESCRIPTION OF EMBODIMENTS

Technical solutions in embodiments of the disclosure will be described clearly and completely in combination with the drawings in the embodiments of the disclosure. Apparently, the described embodiments are merely some of the embodiments of the disclosure, not all of the embodiments. Based on the embodiments in the disclosure, all other embodiments obtained by those skilled in the art without creative work belong to the scope of protection in the disclosure.

An embodiment of the disclosure provides an electronic device. The electronic device may be a smart phone, a tablet computer, a game device, an augmented reality (AR) device, an automobile device, a data storage device, an audio playback device, a video playback device, a laptop computer, a desktop computing device, etc.

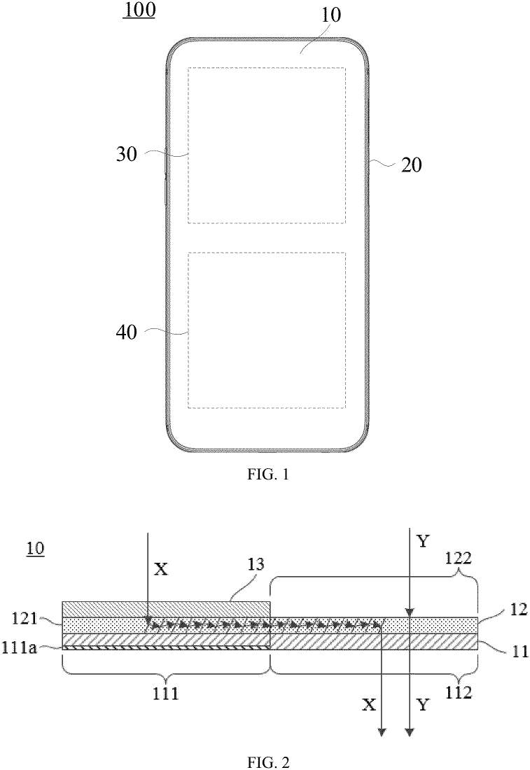

FIG. 1 illustrates a schematic structural view of a first structure of an electronic device according to an embodiment of the disclosure.

The electronic device 100 includes a display screen assembly 10, a housing 20, a circuit board 30, and a battery 40.

Specifically, the display screen assembly 10 is disposed on the housing 20 to form a display surface of the electronic device 100 for displaying information such as images and texts.

Understandably, the display screen assembly 10 may be disposed with a cover plate to protect the display screen assembly 10 and block the display screen assembly 10 from being scratched or damaged by water. The cover plate may be a transparent glass cover plate, so that a user can observe the content displayed by the display screen assembly 10 through the cover plate. For example, the cover plate may be a glass cover plate made of sapphire.

The housing 20 is used to form an external contour of the electronic device 100, so as to accommodate electronic components, functional components, and the like of the electronic device 100, and to seal and protect the electronic components and the functional components inside the electronic device. For example, the functional components such as a camera, a circuit board, and a vibration motor of the electronic device 100 may be disposed inside the housing 20.

The circuit board 30 is disposed inside the housing 20. Specifically, the circuit board 30 may be a main board of the electronic device 100. The circuit board 30 may be integrated with one or more of the functional components such as a processor, a headphone interface, an acceleration sensor, a gyroscope, and a motor. In this situation, the display screen assembly 10 may be electrically connected to the circuit board 30 to control the display of the display screen assembly 10 through the processor on the circuit board 30.

The battery 40 is disposed inside the housing 20. In this situation, the battery 40 is electrically connected to the circuit board 30 to realize that the battery 40 supplies power to the electronic device 100. The circuit board 30 may be disposed with a power management circuit. The power management circuit is used to distribute the voltage provided by the battery 40 to each electronic component in the electronic device 100.

FIG. 2 illustrates a schematic structural view of a display screen assembly of the electronic device illustrated in FIG. 1.

The display screen assembly 10 includes a display screen 11, a coupling grating 12, and an electroluminescent device 13. The display screen 11, the coupling grating 12, and the electroluminescent device 13 are sequentially stacked.

Specifically, the display screen 11 may be a liquid crystal display (LCD) or an organic light-emitting diode (OLED) or other type of display screen.

The display screen 11 includes a first region 111 and a second region 112. The first region 111 may be adjacent to the second region 112, as shown in FIG. 2. In other embodiments, the first region 111 may be disposed around a periphery of the second region 112. The light transmittance of the first region 111 is less than that of the second region 112. For example, the light transmittance of the first region 111 may be 2%, and the light transmittance of the second region 112 may be 20%.

In some embodiments, the first region 111 includes a reflective layer 111a. The reflective layer 111a is located on a side of the first region 111 facing away from the coupling grating 12. The reflective layer 111a is used to reflect light, for example, the light generated in the first region 111 is reflected, so that the light generated in the first region 111 is emitted toward a side of the coupling grating 12, thereby improving the brightness of the first region 111 when displaying information.

In the description of the disclosure, it should be understood that terms such as “first” and “second” are merely used to distinguish similar objects, and cannot be understood as indicating or implying relative importance or implicitly indicating the number of indicated technical features.

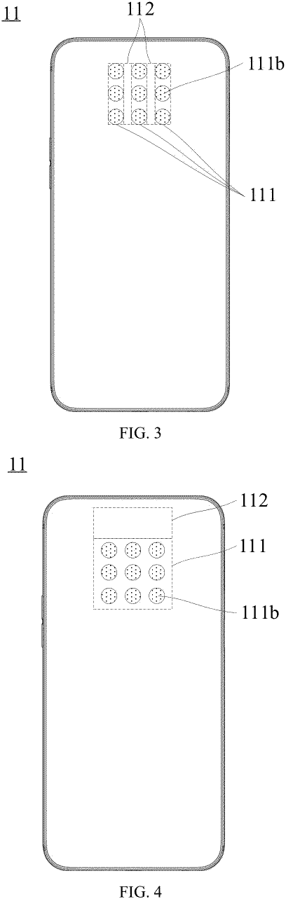

In some embodiments, FIG. 3 illustrates a schematic structural view of a first structure of a display screen of the display screen assembly illustrated in FIG. 2.

Specifically, the first region 111 is disposed with multiple pixels 111b. That is, the first region 111 includes multiple pixels 111b. It can be understood that, when the display screen 11 displays information, in order to make the light generated by the pixels 111b transmit to the outside of the electronic device as much as possible and reduce the loss of light in the electronic device, thereby ensuring the brightness of the display screen 11 when displaying information, a reflective layer may be set at a bottom of the multiple pixels 111b, and the light transmitted to the inside of the electronic device is reflected to the outside of the electronic device through the reflective layer. Therefore, the reflective layer 111a may be a reflective layer disposed at the bottom of the multiple pixels 111b of the first region 111. In practical application, the reflective layer 111a may be anodes at the bottom of the multiple pixels 111b. That is, the reflective layer 111a includes the anodes of the multiple pixels 111b of the first region 111. When the anodes at the bottom of the multiple pixels 111b is used as the reflective layer, the reflectivity can be close to 100%. Therefore, the light transmittance of the pixels 111b are close to 0. In this situation, it can be understood that the light transmittance of the first region 111 is also close to 0.

The second region 112 is not disposed with pixels. As shown in FIG. 3, the second region 112 is a gap region formed by the multiple pixels 111b. It can be understood that the first region 111 is surrounding a periphery of the second region 112 at this time. Since the second region 112 is not disposed with the pixels with the light transmittance close to 0, the light transmittance of the second region 112 is high. In addition, the second region 112 may be disposed with some electronic, such as a pixel driving circuit, and the pixel driving circuit may be made of materials with high light transmittance (such as indium tin oxide abbreviated as ITO) to ensure the light transmittance of the second region 112. It can be understood that the pixel driving circuit may be a driving circuit of the multiple pixels 111b.

In some embodiments, FIG. 4 illustrates a schematic structural view of a second structure of the display screen of the display screen assembly illustrated in FIG. 2.

A difference between the display screen 11 shown in FIG. 4 and that shown in FIG. 3 is that the second region 112 may be separately disposed. That is, the second region 112 is not formed by the gap region between the multiple pixels 111b, but is separately disposed outside the first region 111. For example, the second region 112 may be disposed beside the first region 111 and connected to the first region 111.

The second region 112 may not be disposed with pixels, but the second region 112 may still be disposed with components with high light transmittance such as a pixel driving circuit, and in this case, the second region 112 cannot display information. It can be understood that the second region 112 may be disposed at an edge of the display screen 11. In practical application, a size of the second region 112 may be set smaller, so as to reduce the influence on the display function of the entire display screen 11.

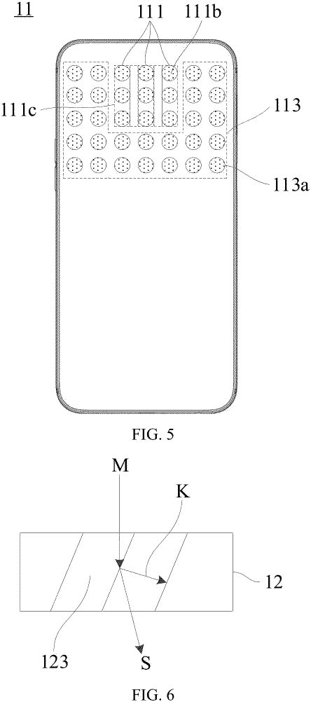

In some embodiments, FIG. 5 illustrates a schematic structural view of a third structure of the display screen of the display screen assembly illustrated in FIG. 2.

The display screen 11 further includes a third region 113. The third region 113 may be disposed at a periphery of the first region 111. The third region 113 is disposed with multiple pixels 113a, and thus the third region 113 can also display information normally. The pixel driving circuit of the first region 111 may be disposed in the third region 113, and the pixel driving circuit of the first region 111 is the driving circuit of the multiple pixels 111b. Therefore, the pixel driving circuit of the multiple pixels 111b does not need to be disposed in the second region 112, so as to further improve the light transmittance of the second region 112.

In some embodiments, the multiple pixels 111b of the first region 111 may form multiple pixel groups 111c. That is, the first region 111 includes multiple pixel groups 111c. Each of the multiple pixel groups 111c includes at least two pixels 111b, and the pixels in each of the multiple pixel groups 111c are connected in parallel.

It can be understood that a pixel density of the third region 113 may be equal to that of the first region 111. When the multiple pixels 111b in the first region 111 are formed into the multiple pixel groups 111c and the pixels in each of the multiple pixel groups 111c are connected in parallel, the parallel pixels in each of the multiple pixel groups 111c may share driving lines. Therefore, the number of driving lines required for the multiple pixels 111b can be reduced, thereby simplifying the driving circuit of the first region 111 as a whole, and facilitating the driving circuit of the first region 111 to be disposed in the third region 113.

As shown in FIG. 2, the coupling grating 12 is disposed on a side of the display screen 11. For example, the coupling grating 12 may be disposed on a display side of the display screen 11. It can be understood that the display side is a side of the display screen 11 that displays information, and can also be understood as a side of the light emitted by an internal light source of the display screen 11.

Specifically, the coupling grating 12 is disposed opposite to the display screen 11. The coupling grating 12 couples and transmits an external light being incident toward the first region 111 of the display screen 11 to be incident toward the second region 112, and emits the external light from the second region 112. It should be noted that the external light refers to light in an external environment, such as sunlight, light emitted by a fluorescent lamp (also referred to as daylight lamp), etc., instead of the light generated by the internal light source of the display screen 11.

The coupling grating 12 includes a first coupling region 121 and a second coupling region 122. The first coupling region 121 is opposite to the first region 111 of the display screen 11, and the second coupling region 122 is opposite to the second region 112 of the display screen 11. The external light being incident on the first coupling region 121 is coupled and transmitted to the second coupling region 122, and emitted from the second coupling region 122 toward the second region 112. Thus, the coupling grating 12 can realize coupling and transmitting the external light being incident toward the first region 111 to be incident toward the second region 112.

For example, as shown in FIG. 2, when the external light X is incident toward the first region 111 of the display screen 11, the external light X is first transmitted to the coupling grating 12, then the external light X is coupled and transmitted by the coupling grating 12 to be incident toward the second region 112 of the display screen 11, and is emitted from the second region 112. That is, the external light X being incident toward the first region 111 is offset by the coupling grating 12 to be incident toward the second region 112, and is emitted from the second region 112.

In addition, the coupling grating 12 further allows an external light being incident toward the second region 112 of the display screen 11 to be transmitted to the second region 112 through the coupling grating 12 and emitted from the second region 112.

For example, as shown in FIG. 2, when the external light Y is incident toward the second region 112 of the display screen 11, the external light Y is first transmitted to the coupling grating 12, and then the external light Y is transmitted to the second region 112 through the coupling grating 12, and is emitted from the second region 112.

FIG. 6 illustrates a schematic view of propagation of light when passing through the coupling grating 12.

The coupling grating 12 includes a periodic grating structure 123. When the external light is transmitted to the coupling grating 12, refraction and transmission occur at the grating structure 123. For example, when the external light M is transmitted to the coupling grating 12, the external light M refracts at the grating structure 123 to form a refracted light (also referred to as refracted ray) K, and transmits to form a transmitted light S. The refracted light K continues to transmit inside the coupling grating 12, and continues to refract at the next grating structure. Since the refracted light K refracts continuously inside the coupling grating 12, the light transmission path is changed. The transmitted light S passes through the coupling grating 12 and is transmitted to the inside of the electronic device, and finally is lost in the electronic device.

It should be noted that with the maturity of coupling grating technology and manufacturing process, the optical performance of the coupling grating can be relatively excellent. In this situation, when the external light refracts and transmits in the coupling grating 12, the refracted light K formed is stronger, while the transmitted light S formed is weaker. Therefore, when the external light passes through the coupling grating 12, the loss of the external light is small, and thus information carried by the external light can be obtained through the refracted light K. The transmission and utilization of the refracted light K are analyzed and described in the present disclosure, and the transmitted light S is ignored.

It should also be noted that the coupling grating 12 in the embodiment of the disclosure may be disposed with a periodic grating structure in a partial region of the first coupling region 121 and the second coupling region 122, and a grating structure is not provided in other regions of the second coupling region 122. Therefore, the region disposed with the periodic grating structure in the coupling grating 12 can couple and transmit the external light, such as the external light X in FIG. 2, while the region not disposed with the grating structure can allow the external light to pass through directly, such as the external light Y in FIG. 2.

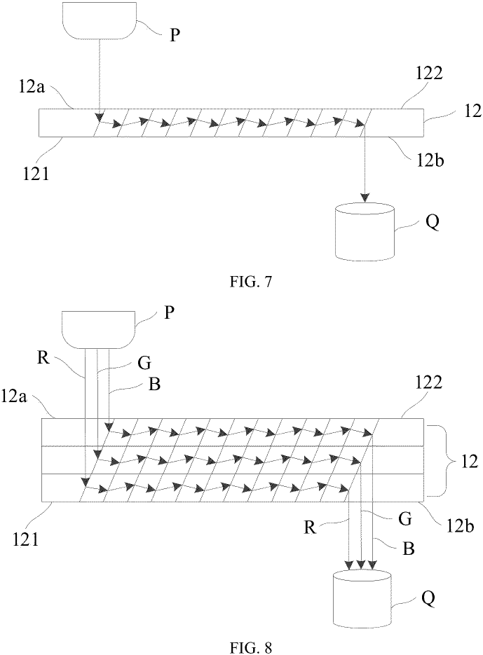

FIG. 7 illustrates a schematic view of a first kind of light propagation in the coupling grating 12 of the display screen assembly illustrated in FIG. 2.

The coupling grating 12 includes an entrance pupil surface 12a and an exit pupil surface 12b. The entrance pupil surface 12a may be understood as a light incident surface of the coupling grating 12, and the exit pupil surface 12b may be understood as a light emitting surface of the coupling grating 12.

When the external light emitted by a light source P is transmitted to the first coupling region 121 of the coupling grating 12, the external light is incident into an interior of the coupling grating 12 from the entrance pupil surface 12a, then transmitted to the second coupling region 122 from the first coupling region 121 in the coupling grating 12, and then the external light is emitted from the exit pupil surface 12b from the second coupling region 122 and transmitted to an optical imaging device Q, so that the optical imaging device Q can obtain an image of the light source P.

It should be noted that although the light source refers to an object that can emit light, such as the sun, the fluorescent lamp and other light sources, any object that can reflect light can be understood as a light source in practical application. For example, when a building reflects sunlight to form reflected light, the building can be understood as a light source, so that an image of the building can be obtained through the optical imaging device. For another example, when the human body reflects sunlight to form reflected light, the human body can also be understood as a light source, so that an image of the human body can be obtained through the optical imaging device.

FIG. 8 illustrates a schematic view of a second kind of light propagation in the coupling grating 12 of the display screen assembly illustrated in FIG. 2.

The external light emitted by the light source P may be mixed color light, for example, the external light emitted by the light source P may include color lights such as red (R), green (G), and blue (B). The coupling grating 12 may be a multi-layer structure. When R, G, B, and other color lights are transmitted to the interior of the coupling grating 12, the R, G, B and other color lights may be refracted at different parts inside the coupling grating 12, and finally emitted from the second coupling region 122 and transmitted to the optical imaging device Q.

As shown in FIG. 2, the electroluminescent device 13 is disposed on a side of the coupling grating 12 facing away from the display screen 11, it can also be understood that the electroluminescent device 13 is disposed on a side facing the user when the display screen assembly 10 displays information.

The electroluminescent device 13 is opposite to the first region 111 of the display screen 11. It can be understood that the electroluminescent device 13 is also opposite to the first coupling region 121 of the coupling grating 12. The electroluminescent device 13 allows the external light to be incident toward the first region 111 of the display screen 11, or blocks the external light from being incident toward the first region 111.

Since the external light is first transmitted to the coupling grating 12 when the external light is incident on the display screen 11, the electroluminescent device 13 can also be understood as allowing the external light to be incident toward the first coupling region 121 of the coupling grating 12, or blocking the external light from being incident toward the first coupling region 121.

The electroluminescent device 13 can be understood as a control switch for external light transmission. The electroluminescent device 13 has a light-shielding state and a light-transmitting state, and can be switched between the light-shielding state and the light-transmitting state. In the light-shielding state, the electroluminescent device 13 does not allow the external light to pass through; and in the light-transmitting state, the electroluminescent device 13 allows the external light to pass through.

When the electroluminescent device 13 is turned on, the electroluminescent device 13 is in a light-shielding state, and in this situation, the electroluminescent device 13 blocks the external light from being incident toward the first region 111 of the display screen 11. When the electroluminescent device 13 is turned off, the electroluminescent device 13 is in a light-transmitting state, and in this situation, the electroluminescent device 13 allows the external light to pass through the electroluminescent device 13 and to be incident toward the first region 111.

Therefore, it can be understood that when the electroluminescent device 13 is turned on, the external light cannot be transmitted to the first coupling region 121 of the coupling grating 12. When the electroluminescent device 13 is turned off, the external light can be transmitted to the first coupling region 121 of the coupling grating 12 through the electroluminescent device 13, then transmitted from the first coupling region 121 to the second coupling region 122, and transmitted from the second coupling region 122 to the second region 112 of the display screen 11 and finally emitted from the second region 112.

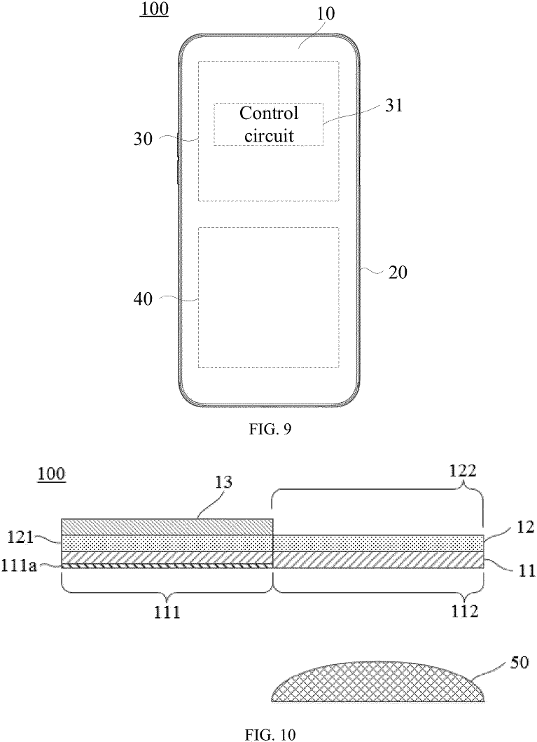

FIG. 9 illustrates a schematic structural view of a second structure of an electronic device 100 according to an embodiment of the disclosure.

The electronic device 100 further includes a control circuit 31. The control circuit 31 may, for example, be disposed on the circuit board 30. The control circuit 31 is electrically connected to the electroluminescent device 13. The control circuit 31 is used to control the electroluminescent device 13 to be turned on or turned off, so that the electroluminescent device 13 allows the external light to be incident toward the first region 111 of the display screen 11 or blocks the external light from being incident toward the first region 111.

It can be understood that the control circuit 31 may include a high-frequency switching switch, such as a switching tube, to switch on or off the electroluminescent device 13 through the high-frequency switching switch.

FIG. 10 illustrates a schematic structural view of a third structure of an electronic device according to an embodiment of the disclosure.

The electronic device 100 further includes an optical imaging device 50 for acquiring an image. The optical imaging device 50 may be, for example, a camera, a video camera, or the like. The optical imaging device 50 is disposed on a side of the display screen 11. It can be understood that in order to realize the hiding of the optical imaging device 50 in the electronic device 100, the optical imaging device 50 may be disposed on a non-display side of the display screen 11. Specifically, the non-display side is a side of the display screen 11 that does not display information, that is, a side of the display screen 11 facing the inside of the electronic device. For the entire electronic device 100, the optical imaging device 50 is disposed at a bottom of the display screen 11, and thus the optical imaging device 50 is invisible to the user.

The optical imaging device 50 is opposite to the second region 112 of the display screen 11. The optical imaging device 50 is used for receiving the external light emitted from the second region 112 to obtain an image.

It can be understood that the external light being incident on the first region 111 of the display screen 11 is emitted from the second region 112 after being coupled and transmitted by the coupling grating 12 and transmitted to the optical imaging device 50. The external light being incident toward the second region 112 is transmitted to the optical imaging device 50 after sequentially passing through the second coupling region 122 of the coupling grating 12 and the second region 112.

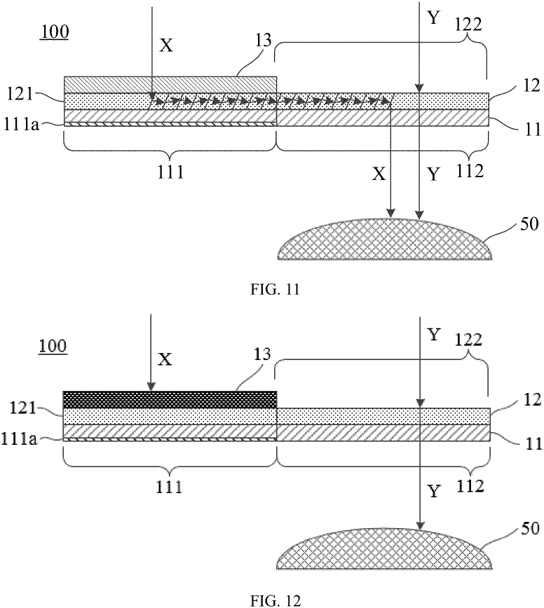

FIG. 11 illustrates a first schematic view of the electronic device acquiring an image according to the embodiment of the disclosure.

It can be understood that since the optical imaging device 50 is opposite to the second region 112 of the display screen 11, and the external light can pass through the second region 112, the optical imaging device 50 can receive the external light passing through the second region 112, so as to obtain an image corresponding to the external light. For example, the optical imaging device 50 can receive the external light passing through the second region 112 to realize functions such as photographing and video recording.

When the electroluminescent device 13 is turned off, that is, when the electroluminescent device 13 allows the external light to be incident toward the first region 111 of the display screen 11, the optical imaging device 50 acquires a first image.

For example, when the external light X is incident toward the first region 111 of the display screen 11, the electroluminescent device 13 allows the external light X to pass through. Then, the external light X is transmitted to the first coupling region 121 of the coupling grating 12, and is coupled and transmitted from the first coupling region 121 to the second coupling region 122 and then emitted from the second coupling region 122 and transmitted to the second region 112 of the display screen 11. Finally, the external light X is emitted from the second region 112 and received by the optical imaging device 50.

In addition, when the external light Y is incident toward the second region 112 of the display screen 11, the external light Y sequentially passes through the second coupling region 122 and the second region 112, and is emitted from the second region 112 and received by the optical imaging device 50.

Therefore, the first image acquired by the optical imaging device 50 includes an image corresponding to the external light X and an image corresponding to the external light Y, and the image corresponding to the external light X overlaps with the image corresponding to the external light Y

FIG. 12 illustrates a second schematic view of the electronic device acquiring the image according to the embodiment of the disclosure.

When the electroluminescent device 13 is turned on, that is, when the electroluminescent device 13 blocks the external light from being incident toward the first region 111 of the display screen 11, the optical imaging device 50 acquires a second image.

For example, when the external light X is incident toward the first region 111 of the display screen 11, the electroluminescent device 13 blocks the transmission of the external light X. Therefore, the external light X cannot continue to be transmitted.

When the external light Y is incident toward the second region 112 of the display screen 11, the external light Y sequentially passes through the second coupling region 122 and the second region 112, and is emitted from the second region 112 and received by the optical imaging device 50.

Therefore, the second image acquired by the optical imaging device 50 includes the image corresponding to the external light Y, but does not include the image corresponding to the external light X.

Understandably, in a real image corresponding to the external light X and the external light Y, the image corresponding to the external light X and the image corresponding to the external light Y should be parts of the real image respectively, and the two images do not overlap. The two images are spliced together as a complete real image.

Therefore, in order to acquire the complete real image, after the optical imaging device 50 acquires the first image and the second image respectively, the electronic device 100 can generate a final image according to the first image and the second image. The final image is the complete real image.

For example, the electronic device 100 can remove image information corresponding to the second image from the first image to obtain a third image. It can be understood that since the first image includes the image corresponding to the external light X and the image corresponding to the external light Y, the second image includes the image corresponding to external light Y, the third image is the image corresponding to external light X.

Then, the electronic device 100 can splice the second image with the third image to obtain the final image.

When removing the image information corresponding to the second image from the first image, the electronic device 100 can process each pixel point of the first image in turn, for example, subtracting a pixel value of a corresponding pixel point of the second image from a pixel value of each pixel point of the first image. After the pixel value of the corresponding pixel point of the second image is successively subtracted from the pixel value of each pixel point of the first image, the pixel value of the pixel point obtained is the pixel value of each pixel point of the third image.

In addition, it can be understood that when the electronic device 100 processes each pixel point of the first image, the first image and the second image can be converted into grayscale images first, and then processed. Moreover, after the first image and the second image are converted into the grayscale images, if the grayscale of the converted first image is different from that of the converted second image, the converted first image and the converted second image can also be adjusted to the same grayscale, and then processed.

In practical application, the electronic device 100 may first control the electroluminescent device 13 to be turned off through the control circuit 31 when photographing or video recording is required, so that the electroluminescent device 13 allows the external light to pass through, and then the first image is acquired through the optical imaging device 50. Then, the control circuit 31 controls the electroluminescent device 13 to be turned on, so that the electroluminescent device 13 blocks the transmission of the external light, and then the second image is acquired through the optical imaging device 50. Finally, the electronic device 100 can generate the final image, that is, the complete real image, according to the first image and the second image.

It should be noted that when the electroluminescent device 13 is turned on, the electroluminescent device 13 does not allow light to pass through, and in this situation, the light generated in the first region 111 of the display screen 11 cannot be transmitted to the outside, so the first region 111 cannot display information normally. Therefore, the electronic device 100 can turn off the display function of the first region 111 when photographing or video recording is required, or turn off the display function of the first region 111 while the electroluminescent device 13 is controlled to be turned on.

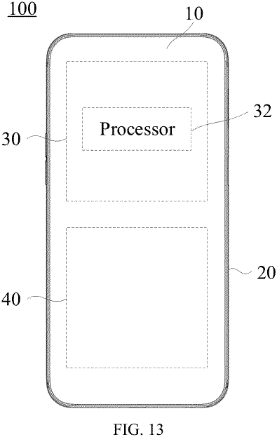

FIG. 13 illustrates a schematic structural view of a fourth structure of an electronic device 100 according to an embodiment of the disclosure.

The electronic device 100 further includes a processor 32. The processor 32 may, for example, be disposed on the circuit board 30. The processor 32 is electrically connected to the optical imaging device 50. When the optical imaging device 50 acquires the first image and the second image respectively, the processor 32 may be used to generate the final image according to the first image and the second image.

For example, the processor 32 may be used to remove the image information corresponding to the second image from the first image to obtain the third image, and to splice the second image with the third image to obtain the final image.

An embodiment of the disclosure provides an image acquisition method, which is applied to the above electronic device 100. The specific implementation of the image acquisition method may refer to the description of the above embodiments, and will not be repeated herein.

Specifically, the embodiment of the disclosure provides the image acquisition method, which is applied to the electronic device, and the electronic device includes:
a display screen assembly, comprising:
a display screen, including a first region and a second region, and light transmittance of the first region being less than light transmittance of the second region;
a coupling grating, disposed on a side of the display screen, wherein the coupling grating is configured to couple and transmit an external light being incident toward the first region to the second region and emitted from the second region; and
an electroluminescent device, disposed on a side of the coupling grating facing away from the display screen, wherein the electroluminescent device is opposite to the first region, and the electroluminescent device is configured to allow the external light to be incident toward the first region or block the external light from being incident toward the first region; and
an optical imaging device, disposed on another side of the display screen, wherein the optical imaging device is opposite to the second region, and the optical imaging device is configured to receive the external light emitted from the second region.

The image acquisition method includes:
acquiring, in response to the electroluminescent device being turned off, a first image through the optical imaging device;
acquiring, in response to the electroluminescent device being turned on, a second image through the optical imaging device; and
generating a final image according to the first image and the second image.

In some embodiments, the generating a final image according to the first image and the second image includes:
removing image information corresponding to the second image from the first image to obtain a third image; and
splicing the second image and the third image to obtain the final image.

In some embodiments, when the electroluminescent device is turned on, the electroluminescent device is in a light-shielding state to block the external light from being incident toward the first region; and

when the electroluminescent device is turned off, the electroluminescent device is in a light-transmitting state to allow the external light to pass through the electroluminescent device and be incident toward the first region.

In some embodiments, the electronic device further includes a control circuit electrically connected to the electroluminescent device.

In some embodiments, the acquiring, in response to the electroluminescent device being turned off, a first image through the optical imaging device includes:

controlling, through the control circuit, the electroluminescent device to be turned off to acquire the first image through the optical imaging device.

The acquiring, in response to the electroluminescent device being turned on, a second image through the optical imaging device includes:

controlling, through the control circuit, the electroluminescent device to be turned on to acquire the second image through the optical imaging device.

The electronic device 100 according to the embodiment of the disclosure can acquire the first image when the electroluminescent device 13 allows the external light to pass through. The first image includes the image corresponding to the external light being incident toward the first region 111 of the display screen 11 and the image corresponding to the external light being incident toward the second region 112 of the display screen 11. When the electroluminescent device 13 blocks the external light from passing through, the second image is acquired. The second image includes the image corresponding to the external light being incident toward the second region 112, but does not include the image corresponding to the external light being incident toward the first region 111. Finally, the final image is acquired according to the first image and the second image, and therefore the optical imaging device 50 can avoid acquiring the external image through the first region 111. Since the light transmittance of the first region 111 is less than that of the second region 112, the influence of the first region 111 with smaller light transmittance on the acquired image can be avoided, and thus the effect of acquiring the image can be improved.

The display screen assembly, the electronic device, and the image acquisition method according to the embodiments of the disclosure are described in detail above. The principles and implementations of the disclosure are described herein with specific examples and the above examples are merely used to help understand the disclosure. In addition, for those skilled in the art, according to an idea of the present disclosure, there may be changes in the specific implementations and application scope. In conclusion, the contents of this description should not be interpreted as a limitation to the present disclosure.

What is claimed is:

1. A display screen assembly, comprising:
a display screen, comprising a first region and a second region, and light transmittance of the first region being less than light transmittance of the second region;
a coupling grating, stacked on a side of the display screen, wherein the coupling grating is configured to couple and transmit an external light being incident toward the first region to the second region and pass through the second region; and
an electroluminescent device, stacked on a side of the coupling grating facing away from the display screen, wherein the electroluminescent device faces to the first region, and the electroluminescent device is configured to allow the external light to be incident toward the first region or block the external light from being incident toward the first region.

2. The display screen assembly according to claim 1, wherein the coupling grating comprises a first coupling region and a second coupling region, the first coupling region faces to the first region, the second coupling region faces to the second region, the external light being incident to the first coupling region is coupled and transmitted to the second coupling region, and the external light is emitted from the second coupling region toward the second region.

3. The display screen assembly according to claim 1, wherein the coupling grating is further configured to allow an external light being incident toward the second region to be transmitted to the second region through the coupling grating and pass through the second region.

4. The display screen assembly according to claim 1, wherein one of the following:
the electroluminescent device is in a light-shielding state to block the external light from being incident toward the first region when the electroluminescent device is turned on; and
the electroluminescent device is in a light-transmitting state to allow the external light to pass through the electroluminescent device and be incident toward the first region when the electroluminescent device is turned off.

5. The display screen assembly according to claim 1, wherein the first region is disposed with a plurality of pixels; and the second region is not disposed with pixels.

6. The display screen assembly according to claim 5, wherein the second region is a gap region formed by the plurality of pixels.

7. The display screen assembly according to claim 5, wherein the display screen further comprises a third region disposed at a periphery of the first region, the third region is disposed with a plurality of pixels, and a pixel driving circuit of the first region is disposed in the third region.

8. The display screen assembly according to claim 7, wherein the first region comprises a plurality of pixel groups, each of the plurality of pixel groups comprises at least two pixels of the plurality of the pixels, and the at least two pixels in the each of the plurality of pixel groups are connected in parallel.

9. The display screen assembly according to claim 8, wherein a pixel density of the third region is equal to a pixel density of the first region.

10. The display screen assembly according to claim 5, wherein a reflective layer is disposed at a bottom of the plurality of pixels in the first region.

11. The display screen assembly according to claim 10, wherein the reflective layer comprises anodes of the plurality of pixels of the first region.

12. An electronic device, comprising:
a display screen assembly, comprising:
a display screen, comprising a first region and a second region, and light transmittance of the first region being less than light transmittance of the second region;
a coupling grating, stacked on a side of the display screen, wherein the coupling grating is configured to couple and transmit an external light being incident toward the first region to the second region and emitted from the second region;
an electroluminescent device, stacked on a side of the coupling grating facing away from the display screen, wherein the electroluminescent device faces to the first region, and the electroluminescent device is configured to allow the external light to be incident toward the first region or block the external light from being incident toward the first region;
an optical imaging device, disposed on another side of the display screen, wherein the optical imaging device faces to the second region, and the optical imaging device is configured to receive external light passed through the second region to thereby obtain an image.

13. The electronic device according to claim 12, further comprising:
a control circuit, electrically connected to the electroluminescent device, wherein the control circuit is configured to control the electroluminescent device to be turned on or turned off, to thereby make the electroluminescent device allow the external light to be incident toward the first region or block the external light from being incident toward the first region.

14. The electronic device according to claim 12, wherein the optical imaging device is configured to acquire a first image in response to the electroluminescent device allowing the external light to be incident toward the first region; and the optical imaging device is configured acquire a second image in response to the electroluminescent device blocking the external light from being incident toward the first region;
wherein the electronic device further comprises:
a processor, electrically connected to the optical imaging device, and the processor is configured to generate a final image according to the first image and the second image.

15. The electronic device of claim 14, wherein the processor is specifically configured to:
remove image information corresponding to the second image from the first image to obtain a third image; and
splice the second image and the third image to obtain the final image.

16. An image acquisition method, applied to an electronic device comprising a display screen assembly and an optical imaging device, the display screen assembly comprising a display screen, a coupling grating, and an electroluminescent device sequentially stacked, wherein the method comprises:
in response to the electroluminescent device being turned off, allowing, by the electroluminescent device facing to a first region of the display screen, an external light to pass through the electroluminescent device and be incident toward the first region; coupling and transmitting, by the coupling grating, the external light being incident toward the first region to a second region of the display screen and pass through the second region, and light transmittance of the first region being less than light transmittance of the second region; receiving, by the optical imaging device facing to the second region, the external light being incident toward the first region and passed through the second region, and acquiring a first image through the optical imaging device;
in response to the electroluminescent device being turned on, blocking, by the electroluminescent device, the external light from being incident toward the first region of the display screen; receiving, by the optical imaging device, an external light being incident toward the second region, and acquiring a second image through the optical imaging device; and
generating a final image according to the first image and the second image.

17. The image acquisition method according to claim 16, wherein generating the final image according to the first image and the second image comprises:
removing image information corresponding to the second image from the first image to obtain a third image; and
splicing the second image and the third image to obtain the final image.

18. The image acquisition method according to claim 16, wherein in response to the electroluminescent device being turned on, blocking, by the electroluminescent device, the external light from being incident toward the first region of the display screen comprises:
in response to the electroluminescent device being in a light-shielding state, blocking, by the electroluminescent device, the external light from being incident toward the first region of the display screen; and
in response to the electroluminescent device being turned off, allowing, by the electroluminescent device facing to a first region of the display screen, an external light to pass through the electroluminescent device and be incident toward the first region comprises:
in response to the electroluminescent device being in a light-transmitting state, allowing the external light to pass through the electroluminescent device and be incident toward the first region.

19. The image acquisition method according to claim 16, wherein the electronic device further comprises a control circuit electrically connected to the electroluminescent device.

20. The image acquisition method according to claim 19, wherein the acquiring a first image through the optical imaging device comprises:
controlling, through the control circuit, the electroluminescent device to be turned off to acquire the first image through the optical imaging device; and
wherein the acquiring a second image through the optical imaging device comprises:
controlling, through the control circuit, the electroluminescent device to be turned on to acquire the second image through the optical imaging device.
